(19) United States
(12) Patent Application Publication
(10) Pub. No.: US 2019/0363067 A1
(43) Pub. Date: Nov. 28, 2019

(54) MULTILAYER SEMICONDUCTOR INTEGRATED CIRCUIT DEVICE

(71) Applicant: KEIO UNIVERSITY, Tokyo (JP)

(72) Inventor: Tadahiro Kuroda, Yokohama-shi (JP)

(73) Assignee: KEIO UNIVERSITY, Tokyo (JP)

(21) Appl. No.: 16/486,471

(22) PCT Filed: Feb. 13, 2018
(86) PCT No.: PCT/JP2018/004788

§ 371 Date: Aug. 15, 2019

(30) Foreign Application Priority Data
Feb. 16, 2017 (JP) 2017-026977

(51) Int. Cl. H01L 25/065; H01L 29/06; H01L 29/08; H01L 29/10; H01L 49/02; H01L 29/36; H01F 38/14; H01L 25/00

(52) U.S. Cl. CPC H01L 25/0657; H01L 29/0684; H01L 29/0804; H01L 29/1004; H01L 24/48; H01L 28/10; H01L 29/36; H01F 38/14; H01L 25/50; H01L 29/0821

(57) ABSTRACT

The invention relates to a multilayer semiconductor integrated circuit device where a stable multilayer structure is achieved. According to the invention, a first semiconductor integrated circuit device is provided with: a first n type trough semiconductor region that penetrates trough a first p type semiconductor body in the direction of the thickness and is connected to the potential of a grounded power supply; and a second n type through semiconductor region that is connected to the potential of a positive power supply, and a second semiconductor integrated circuit device, which has a first electrode and a second electrode respectively connected to the first n type through semiconductor region and the second n type through semiconductor region, is layered on the first semiconductor integrated circuit device.

### TECHNICAL FIELD

The present invention relates to a multilayer semiconductor integrated circuit device, and in particular to a structure for supplying the potential of a power supply between semiconductor chips that are layered on top of each other.

### BACKGROUND ART

In recent years, integrated circuits of which the degree of integration has been increased by layering chips three-dimensionally have been demanded. When memory chips are layered on top of each other, for example, the memory capacity can be increased, and the power consumption that is required for data transfer can be reduced. As for the technology for connecting signals or power supplies between such layered chips, connection by means of wire bonding, connection by means of TAB (tape automated bonding), connection by means of TSV (through silicon via) and the like are known.

From among these, wire bonding has such a problem that the mounting volume becomes large because chips must be layered on top of each other while shifting in such a manner that the openings of the bonding pads for the power supply are not covered. In addition, the current capacity per bonding wire is small and the number of bonding wires has an upper limit, and therefore, such a problem also arises that a sufficient power supply quality cannot be gained.

TAB provides a current capacity that is greater as compared to wire bonding, and the pads for power supply can be arranged in the places other than the periphery of the chips; however, a relatively large gap for allowing the TAB to pass between the layered chips is required, which causes such a problem that the pitch between the chips in the direction in which the chips are layered on top of each other becomes large.

In contrast, TSV is characterized in that all of these problems can be solved. Furthermore, TSV can be used not only in a case where individual chips are layered on top of each other so as to be connected, but also in a case where wafers are layered on top of each other so as to be connected, and thus has such an advantage that the manufacturing efficiency (throughput) can be increased. However, additional processes for creating holes in the silicon substrate, forming an insulating film on the surface of the inner wall of the holes, filling the holes with an electrode, and connecting the electrodes to bumps are necessary, and therefore, such a problem arises that the manufacturing costs increase.

Meanwhile, the present inventor has proposed an electronic circuit which allows wireless data communication between semiconductor integrated circuit chips that are layered on top of each other by using inductive coupling between coils that are formed of wires in the chips, and thus has solved the above-described problems concerning data connection (see Patent Literature 1 or Patent Literature 2).

According to the invention in Patent Literature 1, for example, wireless data communication can be achieved between the layered chips by using inductive coupling between the pair of coils. According to the invention in Patent Literature 2, identical chips are layered on top of each other when mounted in such a manner that wireless data communication can be achieved between the chips, and the power can be supplied by means of wire bonding.

Though TSV can solve the above-described technical problems, the manufacturing costs increase, and therefore, TSV has not been adopted at present in an actual production line. Therefore, the present inventor has proposed manufacturing a multilayer semiconductor integrated circuit device of which the manufacturing costs have been greatly reduced by using a through semiconductor region instead of TSV in order to solve the problems with TSV (see Patent Literature 3). FIG. 24 is a cross-sectional diagram illustrating the main portion of the multilayer semiconductor integrated circuit device that has been proposed by the present inventor. A p type well region 104 and an n type well region 105 are provided in a p⁻ type Si substrate 101 so as to prepare a conventional semiconductor element region.

Here, a p⁺⁺ type well region 102 and an n⁺⁺ type well region 103 that penetrate through the p⁻ type Si substrate 101 are provided in the p⁻ type Si substrate 101 so as to form a power supply wire instead of TSV. Here, through semiconductor regions are provided as the p⁺⁺ type well region 102 and the n⁺⁺ type well region 103 where B (boron) is used as the impurity because doping at a high concentration is possible up to the deep portion of the substrate. Numbers 106, 107, 108, 109, 110, 111, 112, 113, 114, 115, 116 and 117 in the figure respectively denote a p⁺ type contact region, an n type region, an n⁺ type contact region, a p type region, an interlayer insulating film, a contact electrode, a contact electrode, a wire layer, a wire layer, an interlayer insulating film, a surface electrode and a surface electrode.

By layering a number of semiconductor chips like this on top of each other, a multilayer semiconductor integrated circuit device can be implemented. In this case, a sufficiently low wire resistance value is achieved by securing a predetermined area in the entire plane for the p⁺⁺ type well region 102 and the n⁺⁺ type well region 103 that become the through semiconductor regions.

A similar idea to this proposal has already been proposed (see Patent Literature 4). In this proposal, however, the resistance value of the through semiconductor regions is too high to be applied to an actual device, and no means for solving this problem have been disclosed. That is to say, the use of a through semiconductor region as a power supply wire for the connection to the power supply is not considered at all in Patent Literature 4. This is because the resistance value of the semiconductor through hole region is several tens [ohm], and it is clear for those skilled in the art that the semiconductor through hole region makes the voltage drop on the basis of the resistance value too large to supply a stable power supply in the case when it is used as the wire for power supply, though it can be used as a signal wire for a low speed signal. In the case where a number of semiconductor substrates are layered on top of each other, in particular, a high quality power supply voltage is not supplied to a semiconductor substrate in an upper layer, which prevents the semiconductor substrates from functioning as a multilayer integrated circuit device.

### CITATION LIST

### Patent Literature

Patent Literature 1: Japanese Laid-open Patent Publication No. 2005-228981
Patent Literature 2: International Publication Pamphlet No. WO2009/069532
Patent Literature 3: International Publication Pamphlet No. WO2015/136821
Patent Literature 4: Japanese Laid-open Patent Publication No. 2007-250561

### Non-Patent Literature

Non-Patent Literature 1: http://www.disco.co.jp/jp/solution/apexp/polisher/gettering.html
Non-Patent Literature 2: Y. S. Kim et. al., IEDM Tech. Dig., Vol. 365 (2009)
Non-Patent Literature 3: N. Maeda et. al., Symp. VLSI Tech. Dig., Vol. 105 (2010)

### SUMMARY OF INVENTION

### Problems to be Solved by the Invention

As a result of the diligent research by the present inventor, however, it has been found that a problem arises in the case where the concentration of B (boron) is increased in order to lower the resistance of the p type through semiconductor region, for example, in the case where the concentration is 10¹⁸ cm⁻³ or higher, though almost no problem arises in the case where the concentration of B in the p type through semiconductor region is not very high, for example, in the case where the concentration is less than 10¹⁸ cm⁻³. It has also been found that no such problem arises in then type through semiconductor region irrelevant of the concentration of P (phosphorous).

FIG. 25 is a graph illustrating a problem with the flatness in the polishing of the rear surface. In the case where the rear surface is polished in accordance with a CMP (chemical mechanical polishing) method in order to make the p⁺⁺ type well region with a high concentration a through semiconductor region, such a problem arises that the polishing ratio in the p⁺⁺ type well region is low and a protruding portion is formed. FIG. 25 illustrates the results of a case where the conditions for ion implantation were such that the acceleration energy was 50 keV and the dosage was 1.0×10¹⁶ cm⁻², and annealing was carried out for 24 hours, which caused a step of approximately 90.8 nm. Meanwhile, in the case where the rear surface was polished in accordance with a CMP method where an n⁺⁺ type well region with P being doped at a high concentration is the through semiconductor region, the polishing ratio of the n⁺⁺ type well region was not changed as compared to the surrounding Si substrate, and it was confirmed that the rear surface was made flat.

This phenomenon was examined. As for the principal of why the Si substrate can be polished in accordance with CMP, the Si—Si bonds in the Si substrate are polarized, and the Si atoms that have been negatively polarized create Si—OH bases, which are mechanically removed. In the p type Si substrate where Si is doped with B (boron) at a high concentration, however, it is considered that negatively charged B atoms take the OH bases, which makes it difficult for Si—OH bases to be generated, and thus, the polishing rate of CMP is lowered. In contrast, in the n type Si substrate where Si is doped with P (phosphorous) at a high concentration, a conclusion has been reached that the positively charged P atoms do not take the OH bases, which does not prevent Si—OH bases from being generated, and thus, the polishing rate of CMP is not lowered.

In the case where the p type Si substrate is converted to a thin layer of 4 μm or less, a stable layering step is possible when there is a difference in the level of approximately 1 nm over a range of 20 μm×20 μm; however, layering becomes difficult when there is a difference in the level of approximately 90 nm.

Thus, an object of the present invention is to implement a stable multilayer structure.

### Means for Solving the Problems

One embodiment provides a multilayer semiconductor integrated circuit device with at least a first semiconductor integrated device and a second semiconductor integrated device, where the first semiconductor integrated circuit device includes: a first p type semiconductor body; a first n type semiconductor region that is provided in the first p type semiconductor body, and where an element including a transistor is provided; a first p type semiconductor region that is provided in the first p type semiconductor body, and where an element including a transistor is provided; a first n type through semiconductor region that penetrates through the first p type semiconductor body in the direction of the thickness, and at the same time is connected to the potential of a grounded power supply; and a second n type through semiconductor region that penetrates through the first p type semiconductor body in the direction of the thickness, and at the same time is connected to the potential of a positive power supply; and where the second semiconductor integrated circuit device forms a multilayer structure together with the first semiconductor integrated circuit device, and has a first electrode that is electrically connected to the first n type through semiconductor region and a second electrode that is connected to the second n type through semiconductor region.

### Advantageous Effects of the Invention

The disclosed multilayer semiconductor integrated circuit device makes a stable multilayer structure possible.

### BRIEF DESCRIPTION OF DRAWINGS

FIG. 1 is a cross-sectional diagram illustrating the main portion of the multilayer semiconductor integrated circuit device according to an embodiment of the present invention.

FIG. 2 illustrates a profile of the impurity concentration distribution in ion implantation.

FIG. 3 shows diagrams illustrating examples of the arrangement of through semiconductor regions in the multilayer semiconductor integrated circuit device according to an embodiment of the present invention.

FIG. 4 illustrates an equivalent circuit between substrate contact electrodes in the multilayer semiconductor integrated circuit device according to the embodiment of the present invention.

FIG. 5 shows diagrams illustrating examples of the manufacturing process passing on the way of the multilayer semiconductor integrated circuit device according to Example 1 of the present invention.

FIG. 6 shows diagrams illustrating examples of the manufacturing process passing on the way after the state in FIG. 5 of the multilayer semiconductor integrated circuit device according to Example 1 of the present invention.

FIG. 7 shows diagrams illustrating examples of the manufacturing process passing on the way after the state in FIG. 6 of the multilayer semiconductor integrated circuit device according to Example 1 of the present invention.

FIG. 8 is a diagram illustrating examples of the manufacturing process passing on the way after the state in FIG. 7 of the multilayer semiconductor integrated circuit device according to Example 1 of the present invention.

FIG. 9 is illustrating examples of the manufacturing process after the state in FIG. 8 of the multilayer semiconductor integrated circuit device according to Example 1 of the present invention.

FIG. 10 illustrates an equivalent circuit between substrate contact electrodes in the multilayer semiconductor integrated circuit device according to Example 1 of the present invention.

FIG. 11 shows diagrams illustrating modifications of the through semiconductor region and the substrate contact region in the multilayer semiconductor integrated circuit device according to Example 1 of the present invention.

FIG. 12 is a diagram illustrating the multilayer semiconductor integrated circuit device according to Example 2 of the present invention.

FIG. 13 is a diagram illustrating the multilayer semiconductor integrated circuit device according to Example 3 of the present invention.

FIG. 14 is a diagram illustrating the multilayer semiconductor integrated circuit device according to Example 4 of the present invention.

FIG. 15 is a diagram illustrating the multilayer semiconductor integrated circuit device according to Example 5 of the present invention.

FIG. 16 is a diagram illustrating the multilayer semiconductor integrated circuit device according to Example 6 of the present invention.

FIG. 17 is a diagram illustrating the multilayer semiconductor integrated circuit device according to Example 7 of the present invention.

FIG. 18 shows diagrams illustrating the configuration between substrate contact electrodes in the multilayer semiconductor integrated circuit device according to Example 8 of the present invention.

FIG. 19 illustrates an equivalent circuit between substrate contact electrodes in the multilayer semiconductor integrated circuit device according to Example 8 of the present invention.

FIG. 20 shows diagrams illustrating modifications of the through semiconductor region and the substrate contact region in the multilayer semiconductor integrated circuit device according to Example 8 of the present invention.

FIG. 21 shows diagrams illustrating the configuration between substrate contact electrodes in the multilayer semiconductor integrated circuit device according to Example 9 of the present invention.

FIG. 22 is a diagram illustrating an equivalent circuit between substrate contact electrodes in the multilayer semiconductor integrated circuit device according to Example 9 of the present invention.

FIG. 23 shows diagrams illustrating the multilayer semiconductor integrated circuit device according to Example 10 of the present invention.

FIG. 24 is a cross-sectional diagram illustrating the main portion of the multilayer semiconductor integrated circuit device that has been proposed by the present inventor.

FIG. 25 is a graph illustrating a problem with the flatness in the polishing of the rear surface.

### DESCRIPTION OF EMBODIMENTS

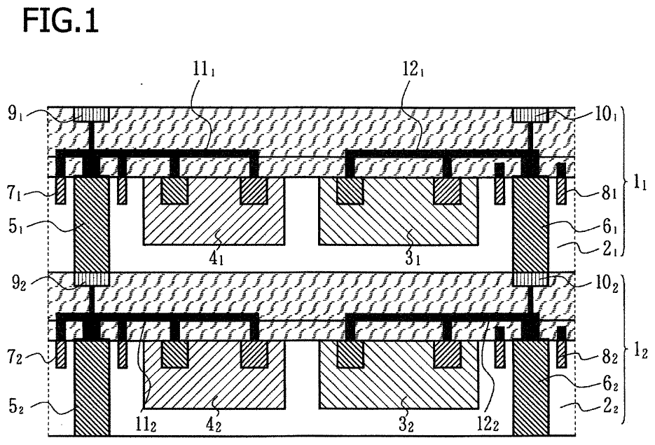

The multilayer semiconductor integrated circuit device according to an embodiment of the present invention is described in reference to FIGS. 1 through 4. FIG. 1 is a cross-sectional diagram illustrating the main portion of the multilayer semiconductor integrated circuit device according to an embodiment of the present invention. Here, a two-layer structure where a first semiconductor integrated circuit device 1₁ and a second semiconductor integrated circuit device 1₂ having the same element configurations are layered on top of each other is illustrated. In the first semiconductor integrated circuit device 1₁, a first n type semiconductor region 3₁, where an element including a transistor is provided, and a first p type semiconductor region 4₁, where an element including a transistor is provided, are provided in a first p type semiconductor substrate 2₁. At the same time, a first n type through semiconductor region 5₁ that is connected to the potential of a grounded power supply and a second n type through semiconductor region 6₁ that is connected to the potential of a positive power supply are provided. The second semiconductor integrated circuit device 1₂ that has a first electrode 9₂ that is electrically connected to the first n type through semiconductor region 5₁ and a second electrode 10₂ that is connected to the second n type through semiconductor region 6₁ is layered on the first semiconductor integrated circuit device 1₁.

In this manner, an n type through semiconductor region can be used when a through semiconductor region having a high impurity concentration is used instead of TSV, of which the manufacturing costs are high, and thus, a step can be effectively prevented from being generated at the time of polishing of the rear surface. As a result, a plurality of semiconductor integrated circuit devices can be layered on top of each other in a stable manner. Here, Patent Literature 3 does not disclose or suggest the point where a first n type through semiconductor region and a second n type through semiconductor region are provided in a p type semiconductor substrate.

In this case, it is desirable for the thickness of the first p type semiconductor substrate 2₁ to be 4 μm or less. In this manner, the first p type semiconductor substrate 2₁ can be converted to a thin layer of which the thickness is 4 μm or less, more preferably 3 μm or less, so that a through semiconductor region can be formed of which the power supply quality can be sufficiently assured even when a type of ion implantation unit that is widely available at present is used. In addition, the total height of the multilayer can be reduced. As a result, communication channels can be arranged at a high concentration or the power consumption for communication can be lowered by reducing the size of the coils for communication through magnetic field coupling.

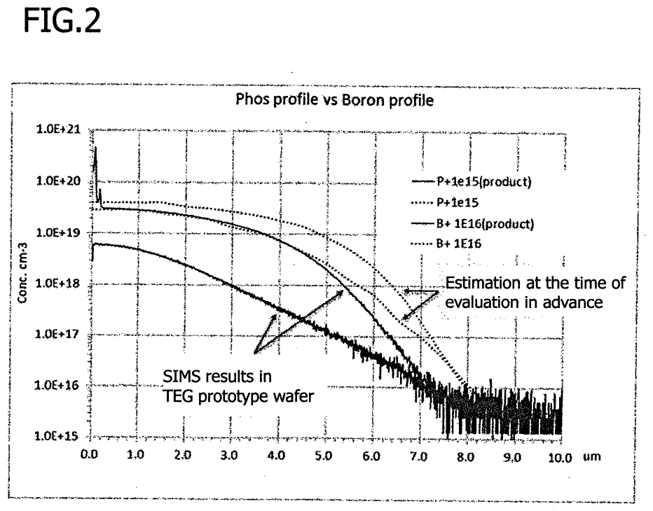

FIG. 2 illustrates a profile of the impurity concentration distribution in ion implantation. In the graph, the lateral axis indicates the depth from the surface of silicon, and the vertical axis indicates the impurity concentration. The solid lines indicate the results of the experiments, and the dotted lines indicate the predictions of the simulations carried out in advance. Here, in the case of P doping, the dosage was 1.0×10¹⁵ cm⁻² and annealing was carried out for 48 hours. In the case of B doping, the dosage was 1.0×10¹⁶ cm⁻² and annealing was carried out for 24 hours. In the case where P was used instead of B, the concentration could be 10×10¹⁸ cm⁻³ or higher on the rear surface at a depth of 5.5 μm or less according to the simulation, whereas it was 3 μm or less in the actual experiment value. The impurity concentration of approximately 4×10¹⁷ cm⁻³ could be gained at the depth of 4 μm, and the average impurity concentration throughout the entirety of the through semiconductor region was 1×10¹⁸ cm⁻³ or higher, and thus it has been found that layers of which the thickness is 4 μm or less can be applied to an actual device.

In order to apply the potential of a grounded power supply to the first p type semiconductor substrate 2₁, a first p type contact region 7₁ that is connected to the potential of the grounded power supply is provided in proximity to the first n type through semiconductor region 5₁. In addition, a second p type contact region 8₁ that is connected to the potential of the grounded power supply is provided in proximity to the second n type through semiconductor region 6₁.

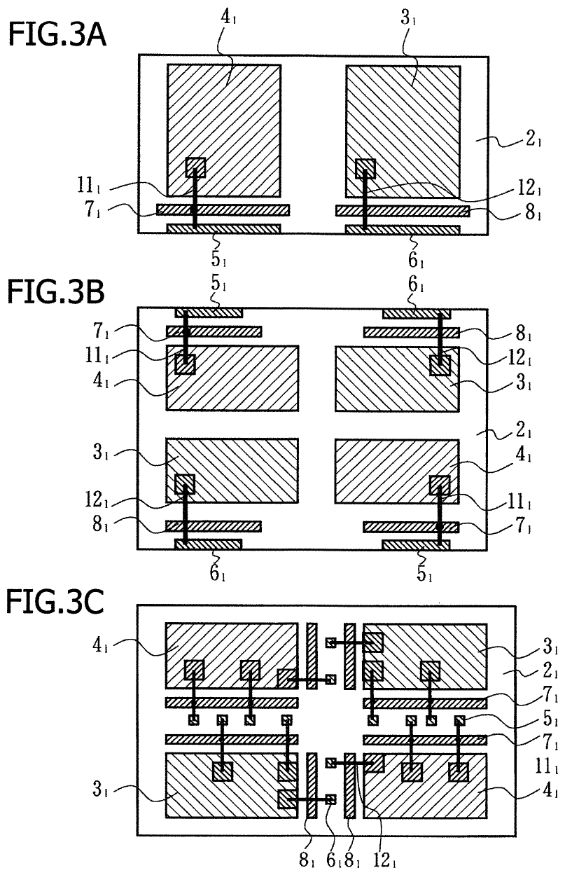

FIG. 3 shows diagrams illustrating examples of the arrangement of through semiconductor regions in the multilayer semiconductor integrated circuit device according to an embodiment of the present invention. FIG. 3(a) illustrates an example where a first n type through semiconductor region 5₁ and a second n type through semiconductor region 6₁ are provided along one side of a first p type semiconductor substrate 2₁, that is to say, a semiconductor chip. FIG. 3(b) illustrates an example where divided first n type through semiconductor regions 5₁ and divided second n type through semiconductor regions 6₁ are provided along one side of a first p type semiconductor substrate 2₁, that is to say, a semiconductor chip. FIG. 3(c) illustrates an example where divided first n type through semiconductor regions 5₁ and divided second n type through semiconductor regions 6₁ are provided as microscopic regions. In any case, a sufficiently low wire resistance value can be achieved by securing a predetermined area as a total area in the plane.

The wire resistance value in this case, that is to say, the sum of the resistance of the resistance value of the through semiconductor region and the contact resistance between the through semiconductor region and the contact electrode can be made sufficiently small, typically 3 mΩ or less, so that a sufficiently high power supply quality can be gained. Incidentally, the resistance value of an Au wire for wire bonding becomes 20 mΩ when the diameter of the Au wire is 25 μmφ, the length is 0.5 mm, and the electrical resistivity is 2.21×10⁻⁸ Ωm. Accordingly, 3 mΩ is enough to reduce the resistance value by one digit as compared to the resistance value of conventional bonding wires, which makes it possible to gain a sufficiently high power supply quality (see Patent Literature 3).

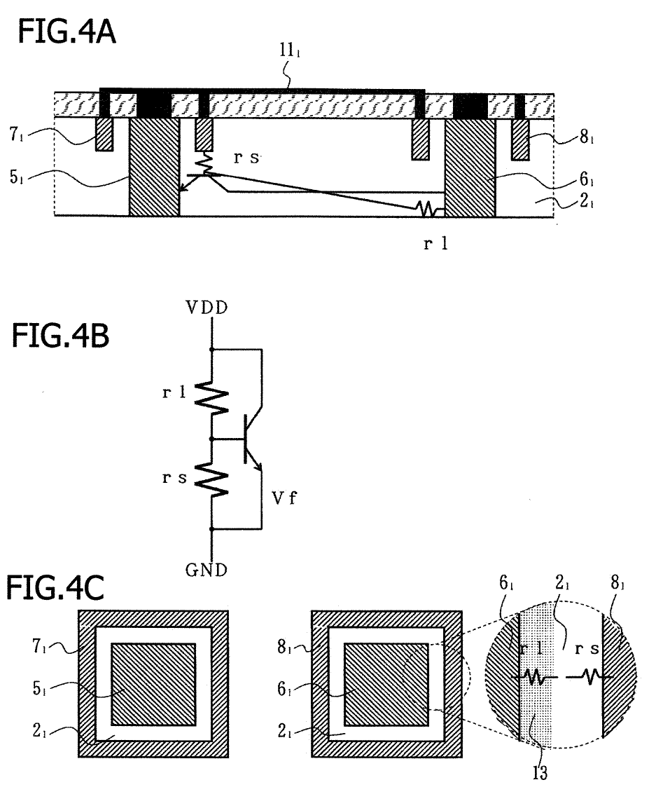

FIG. 4 illustrates an equivalent circuit between substrate contact electrodes in the multilayer semiconductor integrated circuit device according to the embodiment of the present invention. FIG. 4(a) is a schematic cross-sectional diagram, FIG. 4(b) is an equivalent circuit diagram of a parasitic bipolar transistor, and FIG. 4(c) is a plan diagram illustrating a parasitic resistance. As illustrated in FIG. 4(a), a parasitic bipolar transistor is formed with the first n type through semiconductor region 5₁ being the emitter, the first p type semiconductor substrate 2₁ being the base, and the second n type through semiconductor 6₂ being the collector. At this time, a resistance r1 caused by a depletion layer 13 created between the second n type through semiconductor region 6₁ and the first p type semiconductor substrate 2₁ is connected between the collector and the base, whereas the parasitic resistance rs between the first p type contact region 7₁ and the first p type semiconductor substrate 2₁ is connected between the emitter and the base.

At this time, crystal defects are introduced on the polished surface due to rear surface polishing, and a leak current flows through the resistance r1 caused by the depletion layer 13. When V_{DD} is higher than the voltage V_{f} in the forward direction (0.6 V), the parasitic bipolar transistor could be turned on; however, r1 is 1 MΩ or higher, and rs is 1 kΩ or lower, and thus, the risk of the parasitic bipolar transistor being turned on is not necessarily high. In order to suppress the turning on of the parasitic bipolar transistor without fail, however, rs<<r1 may be achieved. In order to do so, a second p type contact region 8₁ may be provided in proximity to the second n type through semiconductor region 6₁ so that the parasitic resistance rs between the first p type contact region 7₁ and the first p type semiconductor substrate 2₁ can be made small.

That is to say, in order for the parasitic bipolar transistor with the first n type through semiconductor region 5₁ being the emitter, the first p type semiconductor substrate 2₁ being the base, and the second n type through semiconductor region 6₁ being the collector to be prevented from being turned on, it is desirable for the resistance rs between the base and the emitter to be smaller than the resistance r1 between the collector and the base.

At this time, the arrangement may allow the first p type contact region 7₁ to surround the periphery of the first n type through semiconductor region 5₁, and the second p type contact region 8₁ to surround the periphery of the second n type through semiconductor region 6₁.

Alternatively, the arrangement may allow the side of the first p type contact region 7₁ that faces the first n type through semiconductor region 5₁ to be longer than the side of the first n type through semiconductor region 5₁ that faces the first p type contact region 6₁ and the side of the second p type contact region 8₁ that faces the second n type through semiconductor region 6₁ to be longer than the side of the second n type through semiconductor region 6₁ that faces the second p type contact region 8₁. Alternatively, the arrangement may allow the first p type contact region 7₁ and the second p type contact region 8₁ to be integrated so as to form a continuous pattern.

Alternatively, the arrangement may allow the first p type contact region 7₁ and the second p type contact region 8₁ to form a single p type semiconductor region in a frame form in such a manner that the first n type through semiconductor region 5₁ and the second n type through semiconductor region 6₁ are arranged inside this single p type semiconductor region in a frame form.

In addition, in order to increase the parasitic resistance between the collector and the base, an n type semiconductor region in a frame form may be provided around the second n type through semiconductor region 6₁ that is connected to the potential of a positive power supply with a portion of the first p type semiconductor substrate 2₁ in between. Instead of this n type semiconductor region in a frame form, multiple n type semiconductor regions in a frame form may be provided.

As for the second semiconductor integrated circuit device 1₂, a second n type semiconductor region 3₂, where an element that includes a transistor is provided, and a second p type semiconductor region 4₂, where an element that includes a transistor is provided, are provided in a second p type semiconductor substrate 2₂. In addition, a third n type through semiconductor region 5₂ that penetrates through the second p type semiconductor substrate 2₂ in the direction of the thickness, and at the same time is connected to the potential of a grounded power supply, and a fourth n type through semiconductor region 6₂ that is connected to the potential of a positive power supply may be provided, and a first electrode 9₂ may be connected to the third n type through semiconductor region 5₂, and a second electrode 10₂ may be connected to the fourth n type through semiconductor region 6₂. In this manner, through semiconductor regions can be provided in the second semiconductor integrated circuit device 2₂ as well in order to make it possible for three or more chips to be layered on top of each other.

It is desirable for no electrodes to be provided on the surfaces of the first n type through semiconductor region 5₁ and the second n type through semiconductor region 6₂ that are exposed from the surface of the first semiconductor integrated circuit device 1₁ that faces the second semiconductor integrated circuit device 1₂, that is to say, from the rear surface of the first semiconductor integrated circuit device 1₁. In this manner, no electrodes are provided on the rear surface, which makes it possible to reduce the manufacturing costs, and at the same time makes it possible to reduce the height of the multilayer.

In the case where no electrodes are provided on the rear surface, a plurality of first plug electrodes may be provided on the surface of the first electrode 9₂ that is provided in the second semiconductor integrated circuit device 1₂, and a plurality of second plug electrodes may be provided on the surface of the second electrode 10₂ that is provided in the second semiconductor integrated circuit device 1₂. By providing these plug electrodes, electrical contact with the rear surfaces of the first n type through semiconductor region 5₁ and the second n type through semiconductor region 6₁ where no rear surface electrodes are provided can be achieved without fail.

The arrangement of the elements in the first semiconductor integrated circuit device 1₁ and the arrangement of the elements in the second semiconductor integrated circuit device 1₂ may be the same. In this manner, the arrangement of the elements in the respective semiconductor integrated circuit devices can be made the same in order to implement, for example, a memory device with a large capacity at a low cost.

Alternatively, the arrangement of the elements in the first semiconductor integrated circuit device 1₁ and the arrangement of the elements in the second semiconductor integrated circuit device 1₂ may be different. In this manner, the arrangement of the elements in the respective semiconductor integrated circuit devices can be made different in order to implement, for example, a multifunctional semiconductor device having a hybrid integrated memory and logic circuit at a low cost.

A plurality of semiconductor integrated circuit devices that are the same as the first semiconductor integrated circuit device 1₁ may be layered on top of each other. By providing such a multilayer structure, a multilayer semiconductor integrated circuit device with the first semiconductor integrated circuit device 1₁ being a nonvolatile memory and the second semiconductor integrated circuit device 1₂ being a controller chip can be implemented.

The first p type semiconductor region 4₁ may be electrically isolated from the first p type semiconductor substrate 2₁ by means of an n type separation layer, whereas the n type separation layer may be exposed from the rear surface of the first p type semiconductor substrate 2₁.

The second n type through semiconductor region 6₁ may be arranged between the first n type through semiconductor region 5₁ and the first n type semiconductor region 3₁. In this case, the first n type through semiconductor region 5₁ that is connected to the potential of a grounded power supply absorbs the collector current from the parasitic bipolar transistor with the first n type region 3₁ being the collector, and therefore, the parasitic bipolar transistor can be effectively prevented from being turned on.

Alternatively, the first p type semiconductor region 4₁ may be arranged between the first n type through semiconductor region 5₁ and the first n type semiconductor region 3₁. In this case, the parasitic bipolar transistor with the first n type region 3₁ being the collector has a long base, and therefore, the current amplification effects of the parasitic bipolar transistor can be made small.

The first semiconductor integrated circuit device 1₁ and the second semiconductor integrated circuit device 1₂ may be provided with a coil for transmitting and receiving a signal. Thus, it is desirable to use inductive coupling through coils for the transmission and reception of a signal. That is to say, in the case where through semiconductor regions are used as signal wires, the signal delay due to their resistance values makes high speed data communication impossible, and therefore, inductive coupling data communication through coils, which makes electrical signal wires unnecessary, becomes optimal.

When semiconductor integrated circuit devices are layered on top of each other, the first semiconductor integrated circuit device 1₁ is fixed to a support substrate, and after that is polished so that the thickness is reduced to approximately 2 μm to 4 μm and the through semiconductor regions (5₁, 6₁) are exposed. Next, the second semiconductor integrated circuit device 1₂ having the same or a different element structure may be layered on the first semiconductor integrated circuit device 1₁ in such a manner that the surface electrodes (9₂, 10₂) make contact with the rear surface of the through semiconductor regions (5₁, 6₁). In the case where another semiconductor integrated circuit device is layered, the second semiconductor integrated circuit device 1₂ may also be polished so that the high impurity concentration regions become through semiconductor regions. Here, the through semiconductor regions are high impurity concentration regions, and therefore, contact electrodes may be made of Al, Cu or W. Chips during the layering process require no pads, for example, and therefore, surface electrodes may be formed in the uppermost layer of multilayer wires formed of Cu. Here, a multilayer structure made of a contact layer (TiN, TaN)/a barrier layer (TiW, TaN)/a metal may be adopted in order to achieve a good ohmic contact.

This layering process may be carried out at the wafer stage or after the chips have been cut out. Furthermore, wafers that have been reconstructed through KGD (Known Good Die) may be used as the wafers. That is to say, good chips are found on the wafer through testing, individual chips are cut out through dicing and sorted out so as to discard the defective chips, and only the good chips are realigned on a support substrate in a wafer form so as to be fixed with an adhesive, and thus, a wafer may be reconstructed.

### Example 1

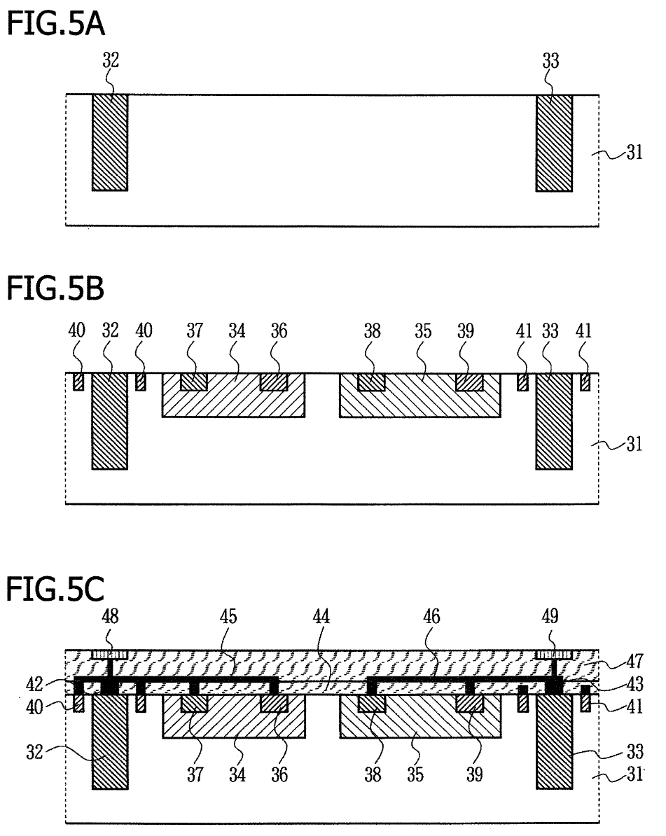

Next, the multilayer semiconductor integrated circuit device according to Example 1 of the present invention is described in reference to FIGS. 5 through 11. In this example, three memory chips that are the same are layered on top of each other. First, as illustrated in FIG. 5(a), a dosage of 1×10¹⁶ cm⁻² of P is ion injected into a p⁻ Si substrate 31 with the acceleration energy of 200 keV so as to form n⁺⁺ type well regions 32 and 33 having a size of 100 μm×100 μm. Next, heat treatment is carried out at 1050° C. for 50 hours in order to activate the implanted ions, and at the same time diffuse the ions deeply in the direction of the thickness of the substrate. Here, the oxide film that has attached to the surface of the substrate as a result of the heat treatment is removed if necessary.

Next, as illustrated in FIG. 5(b), a p type well region 34 and an n type well region 35 that become element forming regions are formed in the p⁻ type Si substrate 31 in the same manner as in the conventional manufacturing process. Next, a p⁺ type contact region 36 is formed in the p type well region 34, and at the same time, an n type region 37 that becomes a source region or a drain region is formed, and a gate electrode (not shown) is provided so as to form an n channel MOSFET. Meanwhile, an n⁺ type contact region 38 is formed on the n type well region 35, and at the same time, a p type region 39 that becomes a source region or a drain region is formed, and a gate electrode (not shown) is provided so as to form a p channel MOSFET. In addition, p⁺ type substrate contact regions 40 and 41 are formed so as to surround the n⁺⁺ type well regions 32 and 33.

Next, as illustrated in FIG. 5(c), contact electrodes 42 and 43 made of Cu are formed on the surface of the n⁺⁺ type well regions 32, 33 and the p⁺ type substrate contact regions 40, 41, and at the same time, a wire layer 45, 46 is formed using a multilayer wiring technology. Here, the contact electrode 43 formed on the p⁺ type substrate contact region 41 is connected to the wire 45. Next, a surface electrode 48 made of Al or Cu that is connected to the contact electrode 42 and a surface electrode 49 made of Al or Cu that is connected to the contact electrode 43 are formed. At this time, coils (not shown) for inductive coupling data communication are formed using the multilayer wires. In addition, polishing is carried out in order to flatten the surface. Here, the numbers 44 and 47 in the figure are interlayer insulating films made of SiO₂.

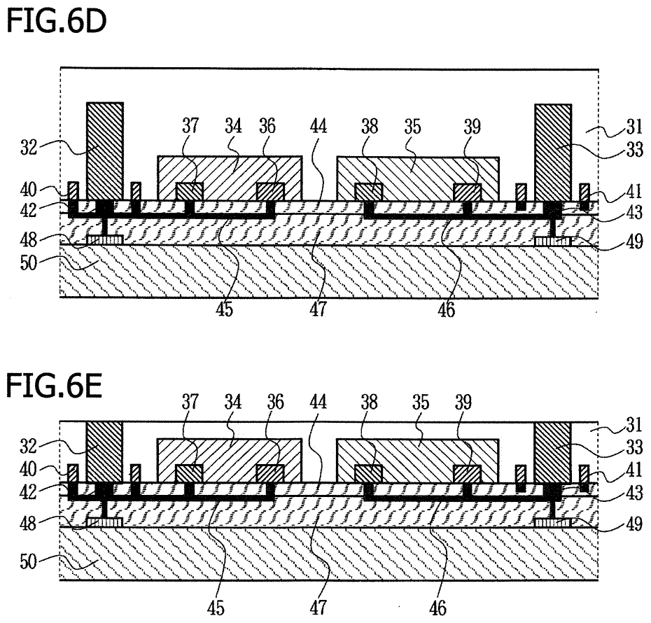

Next, as illustrated in FIG. 6(d), the substrate is temporarily joined to a support substrate 50 made of an Si substrate in such a manner that the surface where the surface electrodes 48 and 49 are formed makes contact with the support substrate 50. Next, as illustrated in FIG. 6(e), the p⁻ type Si substrate 31 is grinded to a predetermined thickness, and after that is polished in accordance with a chemical mechanical polishing (CMP) method so that the thickness becomes 3 μm.

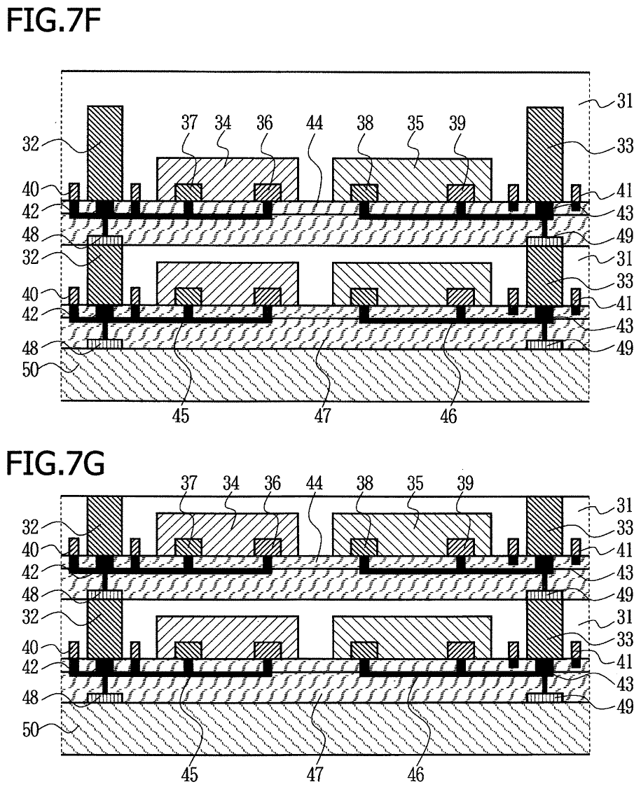

Next, as illustrated in FIG. 7(f), another semiconductor wafer that has been fabricated in the process up to the step in FIG. 5(c) is layered. At this time, the semiconductor wafers are layered on top of each other in such a manner that the exposed surface of the n⁺⁺ type well regions 32 and 33 in the semiconductor integrated circuit device in the first layer make contact with the surface electrodes 48 and 49 in the semiconductor integrated circuit device in the second layer. In this case, pressure is applied at the normal temperature in the layered state so that silicon and the silicon oxide film achieve solid-state welding through diffusion, and as a result, the surface electrodes 48 and 49 in the semiconductor integrated circuit device in the second layer closely adhere to and are electrically connected to the n⁺⁺ type well regions 32 and 33 in the semiconductor integrated circuit device in the first layer.

Next, as illustrated in FIG. 7(g), the p⁻ type Si substrate 31 in the second layer is grinded to a predetermined thickness, and after that is polished in accordance with a chemical mechanical polishing method so that the thickness of the p⁻ type Si substrate 31 becomes 3 μm.

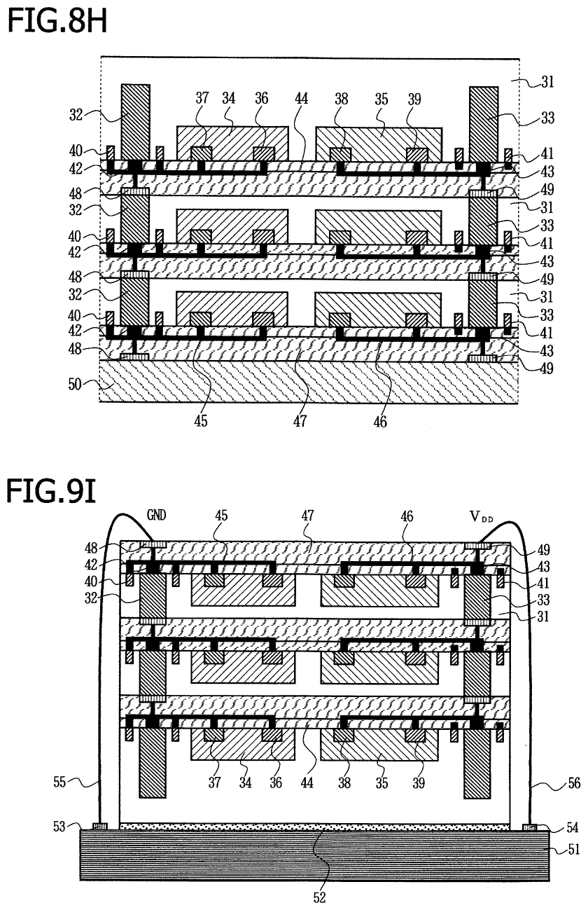

Next, as illustrated in FIG. 8(h), another semiconductor wafer that has been fabricated in the process up to the step in FIG. 5(c) is again layered. At this time as well, the semiconductor wafers are layered on top of each other in such a manner that the exposed surface of the n⁺⁺ type well regions 32 and 33 in the semiconductor integrated circuit device in the second layer and the surface electrodes 48 and 49 in the semiconductor integrated circuit device in the third layer make contact with each other. At this time as well, pressure is applied at the normal temperature in the layered state so that silicon and the silicon oxide film achieve solid-state welding through diffusion.

Next, as illustrate in FIG. 9(k), the layered wafer is removed from the support substrate 50 and is divided into chips of a predetermined size, which are then fixed onto a package substrate 51 using an adhesive 52. Next, a power supply pad 53 for GND or the like and the surface electrode 48 that is connected to the n⁺⁺ type well region 32 are connected through a bonding wire 55. Meanwhile, a power supply pad 54 to which V_{DD} is to be applied and the surface electrode 59 that is connected to the n⁺⁺ type well region 33 are connected through a bonding wire 56, and thus, the basic structure of the multilayer semiconductor integrated circuit device according to Example 1 of the present invention is complete. Here, it is desirable for the thickness of the p-type Si substrate in the third layer not to be reduced from the point of view of the ease of handling and of securing the mechanical strength.

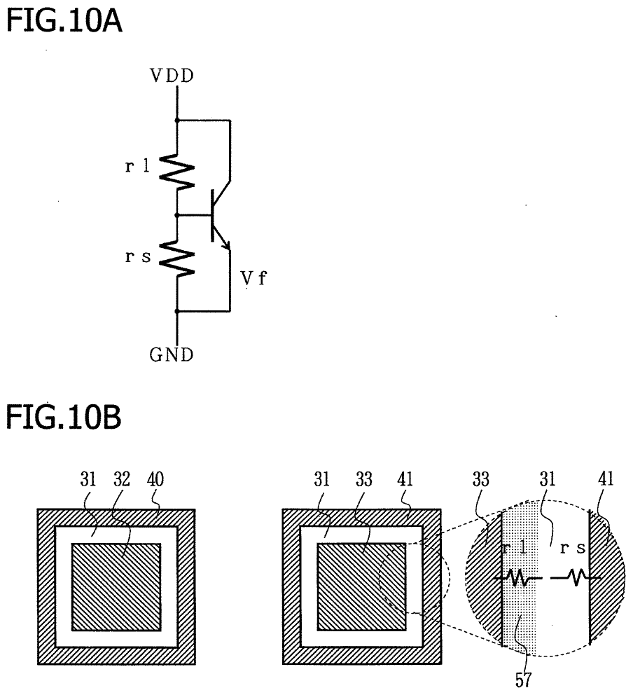

FIG. 10 illustrates an equivalent circuit between substrate contact electrodes in the multilayer semiconductor integrated circuit device according to Example 1 of the present invention. FIG. 10(a) is a diagram illustrating an equivalent circuit, and FIG. 10(b) is a diagram illustrating a parasitic resistance. In the same manner as in FIG. 4(a), the equivalent circuit in FIG. 10(a) illustrates an npn parasitic bipolar transistor with the n⁺⁺ type well region 32 being the emitter, the p⁻ type silicon substrate 31 being the base, and the n⁺⁺ type well region 33 being the collector. As illustrated in FIG. 10(b), the parasitic resistance r1 between the collector and the base is generated as crystal defects caused by the polishing in the depletion layer 57 between the n⁺⁺ type well region 33 and the p⁻ type Si substrate. Meanwhile, the parasitic resistance rs between the emitter and the base becomes the resistance between the n⁺⁺ type well region 32 and the p⁻ type Si substrate, and can be reduced by making the p type substrate contact region 40 be closer to the n⁺⁺ type well region 32. Here, the distance between the two is 10 μm.

As described above, in Example 1 of the present invention, the n⁺⁺ type well region that has been doped with P so as to be a high impurity concentration well region that cannot be expected as a through wire according to the prior art is used as a power supply wire for the multilayer semiconductor integrated circuit device, and therefore, a step can be prevented from being created at the time of polishing on the rear surface. In the same manner as TSV, it is not necessary to shift the chips when the chips are layered on top of each other. In addition, it is not necessary to insert a TAB between the chips, and therefore, the size can be made smaller three-dimensionally.

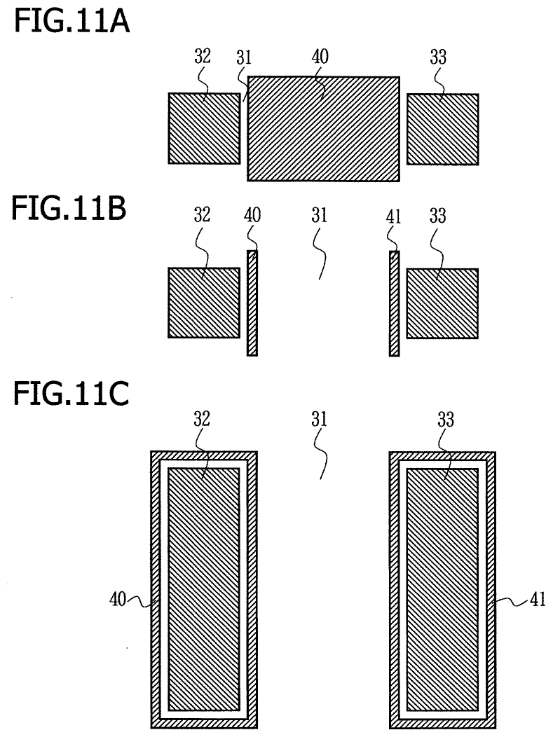

FIG. 11 shows diagrams illustrating modifications of the through semiconductor region and the substrate contact region in the multilayer semiconductor integrated circuit device according to Example 1 of the present invention. In Example 1, as illustrated in FIG. 10(b), square n⁺⁺ type well regions 32 and 33 are surrounded by p⁺ type substrate contact regions 40 and 41 in a frame form; however, the configuration is not limited to this.

As illustrated in FIG. 11(a) for example, a p⁺ type substrate contact region 40 in a uniform pattern may be provided between the n⁺⁺ type well region 32 and the n⁺⁺ type well region 33. Alternatively, as illustrated in FIG. 11(b), p⁺ type substrate contact regions 40 and 41, which are longer than the side of the n⁺⁺ type well region 32 and the side of the n⁺⁺ type well region 33 may be provided along the side of the n⁺⁺ type well region 32 and the side of the n⁺⁺ type well region 33 on the side where the two face each other. Furthermore, as illustrated in FIG. 11(c), the n⁺⁺ type well region and the n⁺⁺ type well region 33 may be rectangular, and these n⁺⁺ type well regions may be surrounded by p⁺ type substrate contact regions 40 and 41 in a frame form. In this case, the n⁺⁺ type well regions 32 and 33 have a rectangular shape where the shorter sides have a length of 100 μm, for example.

### Example 2

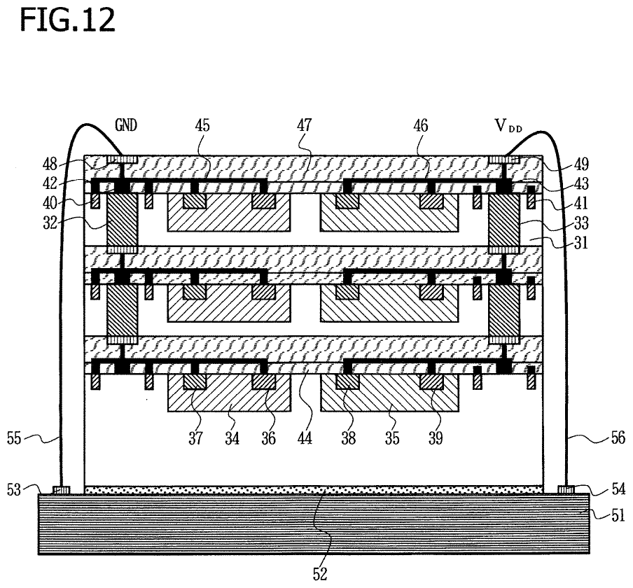

Next, the multilayer semiconductor integrated circuit device according to Example 2 of the present invention is described in reference to FIG. 12, which illustrates only the final structure since the basic manufacturing process and the structure are the same as in Example 1. FIG. 12 is a diagram illustrating the multilayer semiconductor integrated circuit device according to Example 2 of the present invention where no n⁺⁺ type well region that would become a through semiconductor region has been formed in the semiconductor integrated circuit device in the final layer (the third, the lowest layer in the figure), and the structure of the remaining part is the same as in Example 1.

Thus, the chip in the final layer needs not to transfer the power supply to the next layer, and therefore does not need a high purity well region. Accordingly, in the case where layered chips include a chip having different properties, the chip having different properties can be arranged in the final layer. The process for forming an n⁺⁺ type well region becomes unnecessary in the chip that forms the final layer, and therefore, it becomes possible to reduce the manufacturing costs.

### Example 3

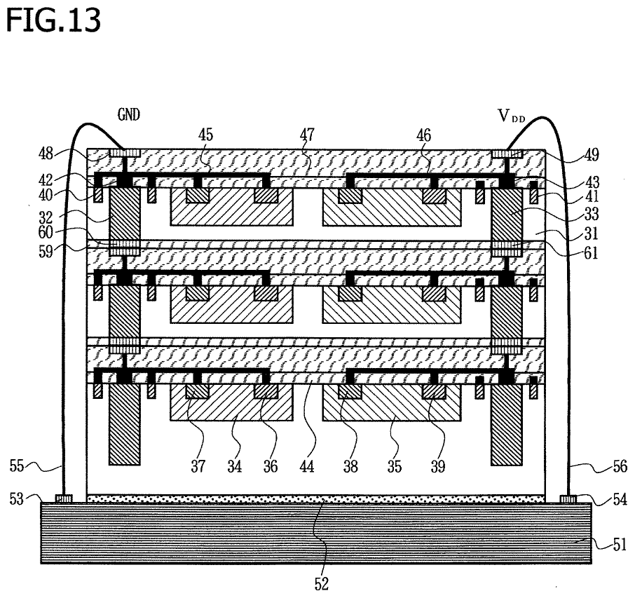

Next, the multilayer semiconductor integrated circuit device according to Example 3 of the present invention is described in reference to FIG. 13, which illustrates only the final structure since the basic manufacturing process and the structure are the same as in Example 1. FIG. 13 is a schematic cross-sectional diagram illustrating the multilayer semiconductor integrated circuit device according to Example 3 of the present invention, where rear surface electrodes 60 and 61 are provided by using Cu on the surface of the n⁺⁺ type well regions 32 and 33 that are exposed from the rear surface, and at the same time, an SiO₂ protective film 59 is provided, and the structure of the remaining part is the same as in Example 1.

The junctions at this time are normal temperature junctions under pressure between the metals of the rear surface electrodes 60, 61 and the front surface electrodes 48, 49 after the surfaces of the metals have been activated, that is to say, junctions by means of solid phase welding through intermetal diffusion. Thus, it is possible to layer chips on top of each other even when rear surface electrodes are provided on each chip by using solid state welding through intermetal diffusion.

### Example 4

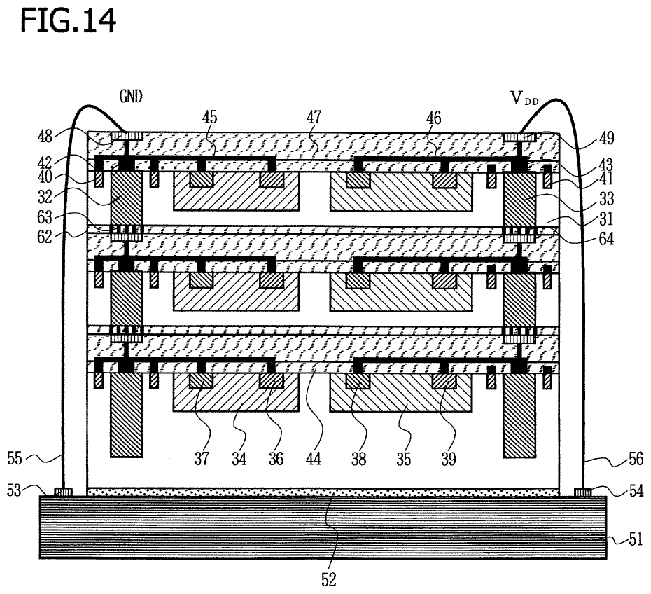

Next, the multilayer semiconductor integrated circuit device according to Example 4 of the present invention is described in reference to FIG. 14, which illustrates only the final structure since the basic manufacturing process and the structure are the same as in Example 1. FIG. 14 is a schematic cross-sectional diagram illustrating the multilayer semiconductor integrated circuit device according to Example 4 of the present invention where surface plug electrodes 63 and 64 are provided on the front surface electrodes 48 and 49 in the semiconductor integrated circuit device in the second layer so that the surface plug electrodes 63 and 64 can make contact with the n⁺⁺ type well regions 32 and 33 in the semiconductor integrated circuit device in the first layer, and the structure of the remaining part is the same as in Example 1.

The junctions at this time are made by means of solid phase welding where the silicon and the silicon oxide film diffuse. Thus, surface plugs electrodes 63 and 64 can be provided on the front surface side of the semiconductor integrated circuit device in the second or higher layer so that the electrical connection with the multilayer integrated circuit device in the first layer can be established without fail.

### Example 5

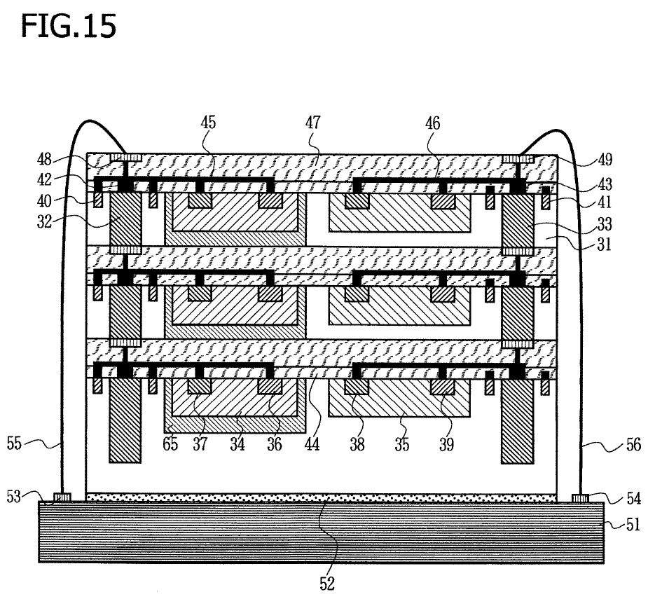

Next, the multilayer semiconductor integrated circuit device according to Example 5 of the present invention is described in reference to FIG. 15. Example 5 is basically the same as Example 1, except that the p⁺ type well region that is an element formation region is covered with an n type deep well region. In this case, the n type deep well region 65 is formed in advance, and after that, the p type well region 34 is formed, and the rear surface is polished until the bottom of the n type deep well region 65 is exposed.

In Example 5, the n type deep well region 65 has been polished so as to be thinner until the bottom thereof is exposed from the polished surface; however, the p type well region 34 that is an element formation region is not directly exposed, and therefore, the element properties are only affected microscopically.

### Example 6

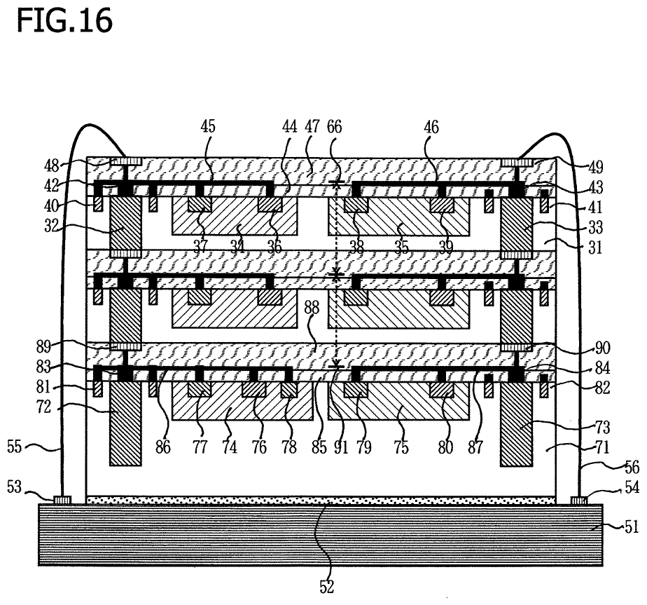

Next, the multilayer semiconductor integrated circuit device according to Example 6 of the present invention is described in reference to FIG. 16, where Example 6 is the same as Example 1, except that the type of the layered semiconductor integrated circuit devices is different, and therefore, only the final structure is described. FIG. 16 is a schematic cross-sectional diagram illustrating the multilayer semiconductor integrated circuit device according to Example 6 of the present invention, where a controller chip unlike a memory chip is provided in the third layer, unlike in the first and second layers in the step in FIG. 8(h).

In the controller chip in this case, an n⁺⁺ type well region 72 is provided in a p⁻ type Si substrate 71 in the same location as the n⁺⁺ type well region 32 that is provided in the memory chips, and an n⁺⁺ type well region 73 is provided in the same location as the n⁺⁺ type well region 33. Next, a p type well region 74 and an n type well region 75 that become element formation regions are formed in the p⁻ type Si substrate 71. At this time, p⁺ type substrate contact regions 81 and 82 are formed around the periphery of the n⁺⁺ type well regions 72 and 73. Next, a p⁺ type contact region 76 is formed in the p type well region 74, and at the same time, n type regions 77 and 78 that become a source region or a drain region are formed, and a gate electrode (not shown) is provided so as to form an n channel MOSFET. Meanwhile, an n⁺ type contact region 79 is formed in the n type well region 75, and at the same time, a p type region 80 that becomes a source region or a drain region is formed, and a gate electrode (not shown) is provided so as to form a p channel MOSFET.

Next, contact electrodes 83 and 84 made of Cu are formed on the surface of the n⁺⁺ type well region 72 and the n⁺⁺ type well region 73, and at the same time, a multilayer wiring technology is used to form a wire layer 86, 87. Next, a surface electrode 89 made of Al, Cu or W that is connected to the contact electrode 83 and a surface electrode 90 made of Al, Cu or W that is connected to the contact electrode 84 are formed.

At this time, a communication coil 91 for inductive coupling data communication is formed by using multilayer wires in such a manner that the location thereof becomes the same as that of the communication coil 66 provided in the memory chip when the chips are layered on top of each other. In addition, polishing is carried out in order to flatten the surface. Here, the numbers 85 and 88 in the figure are interlayer insulating films made of SiO₂.

Next, the rear surface of the p⁻ type Si substrate 71 that forms the controller chip is fixed onto a package substrate 51 using an adhesive 52. After that, the power supply pad 53 for grounding and the surface electrode 58 that is connected to the n⁺⁺ type well region 32 are connected through a bonding wire 55. Meanwhile, the power supply pad 54 to which V_{DD} is to be applied and the surface electrode 49 that is connected to the n⁺⁺ type well region 33 are connected through a bonding wire 56, and thus, the basic structure of the multilayer semiconductor integrated circuit device according to Example 6 of the present invention is complete.

As described above, in Example 6 of the present invention, a technology for making layers thinner and a multilayer technology are combined for use to make it possible to implement at low costs a compact semiconductor memory device where a memory chip and a controller chip for driving and controlling the memory chip are layered.

### Example 7

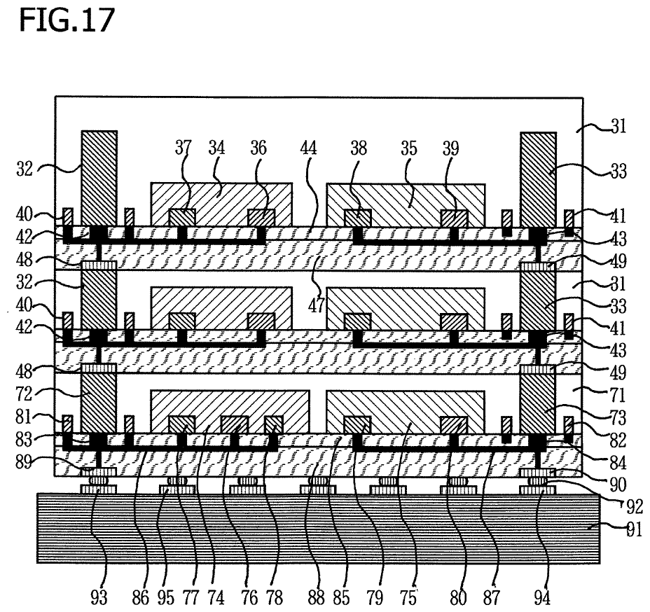

Next, the multilayer semiconductor integrated circuit device according to Example 7 of the present invention is described in reference to FIG. 17. In Example 7, a semiconductor memory device having the same functions as the semiconductor memory device in Example 6 is formed without using wire bonding.

The layered wafer is removed from the support substrate and is divided into chips of a predetermined size. After that, surface electrodes 89 and 90 of a controller chip are deposited onto a GND pad 93 and a V_{DD} power supply pad 94 on top of a package substrate 91 through bumps 92, and as a result, the basic structure of the multilayer semiconductor integrated circuit device according to Example 7 of the present invention is complete. At this time, the space between a package substrate 91 and the controller chip is filled with an underfill resin (not shown). Here, the number 95 in the figure is a signal pad, which is connected to a pad (not shown) provided on the surface of the controller chip through a bump 92.

In Example 7 of the present invention, the controller chip is electrically connected to the package substrate through pads without using a bonding wire, and therefore, space for arranging bonding wires becomes unnecessary, which makes it possible to reduce the space.

### Example 8

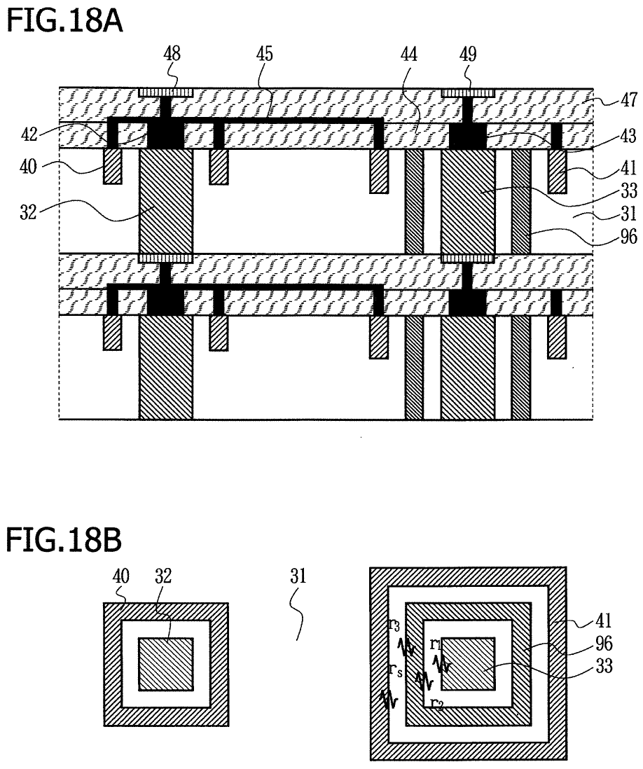

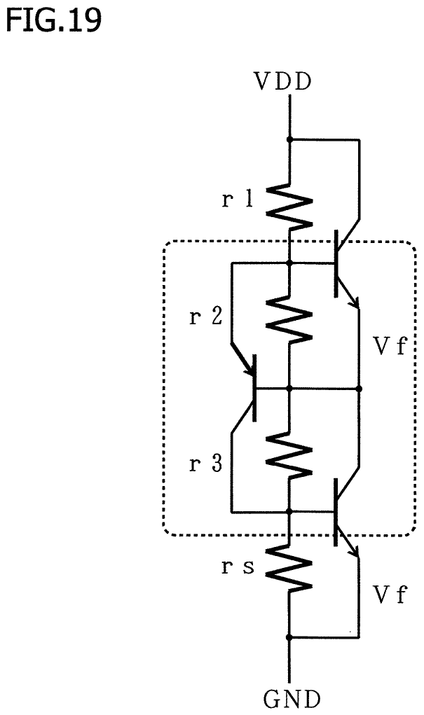

Next, the multilayer semiconductor integrated circuit device according to Example 8 of the present invention is described in FIGS. 18 and 19. Example 8 is the same as Example 1, except that an n⁺⁺ type guard ring is provided around the periphery of the n⁺⁺ type well region for V_{DD} in order to increase the resistance between the collector and the base. In order to make the description simpler, the p type well region and the n type well region are omitted, and at the same time, the illustrated multilayer structure has two layers.

FIG. 18 shows diagrams illustrating the configuration between substrate contact electrodes in the multilayer semiconductor integrated circuit device according to Example 8 of the present invention. FIG. 18(a) is a cross-sectional diagram, and FIG. 18(b) is a plan diagram. As illustrated in FIG. 18(a), an n⁺⁺ type guard ring 96 is provided between the n⁺⁺ type well region 33 and the p⁺ type substrate contact region 41.

In this case, as illustrated in FIG. 18(b), a resistance r1 is generated due to a depletion layer between the n⁺⁺ type well region 33 and the p⁻ type Si substrate 31, and resistances r2 and r3 are generated due to a depletion layer between the p⁻ type Si substrate 31 and the p⁺ type guard ring 96. In addition, the parasitic resistance rs between the emitter and the base becomes the resistance between the n⁺⁺ type well region 32 and the p⁻ type Si substrate 31.

FIG. 19 illustrates an equivalent circuit between substrate contact electrodes in the multilayer semiconductor integrated circuit device according to Example 8 of the present invention. A thyristor structure surrounded by a broken line is formed between the n⁺⁺ well region 32/p⁻ type Si substrate 31/n⁺⁺ type guard ring 96/p⁻ type Si substrate 31/n⁺⁺ type well region 33. Therefore, the voltage that is applied between the emitter and the base of the parasitic npn bipolar transistor on the n⁺⁺ type well region 32 side becomes V_{DD} multiplied by rs/(rs+r3+r2+r1), which is smaller than V_{f}, and therefore, it becomes possible to effectively prevent the parasitic npn bipolar transistor from turning on.

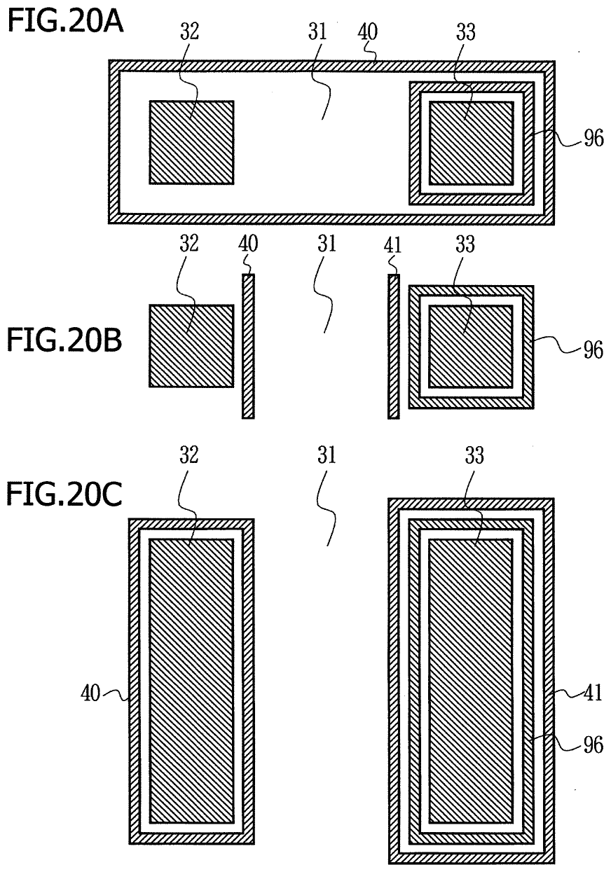

FIG. 20 shows diagrams illustrating modifications of the through semiconductor region and the substrate contact region in the multilayer semiconductor integrated circuit device according to Example 8 of the present invention. In FIG. 20(a), the n⁺⁺ type well region 32 and the n⁺⁺ type well region 33 are surrounded by a simple p⁺ type substrate contact region in a frame form. Alternatively, as illustrated in FIG. 20(b), p⁺ type substrate contact regions 40 and 41 that are longer than any side of the n⁺⁺ type guard ring 96 may be provided along the n⁺⁺ type well region 32 and the n⁺⁺ type well region 33 on the side where the n⁺⁺ type well regions face each other. Furthermore, as illustrated in FIG. 20(c), the n⁺⁺ type well region 32 and the n⁺⁺ well region 33 may be rectangular, and these n⁺⁺ well regions may be surrounded by p⁺ type substrate contact regions 40 and 41 in a frame form. In this case, the n⁺⁺ type well regions 32 and 33 have a rectangular shape where the length of a shorter side is 100 μm, for example. Here, this structure where the n⁺⁺ type guard ring is provided can be applied to Examples 2 through 7.

### Example 9

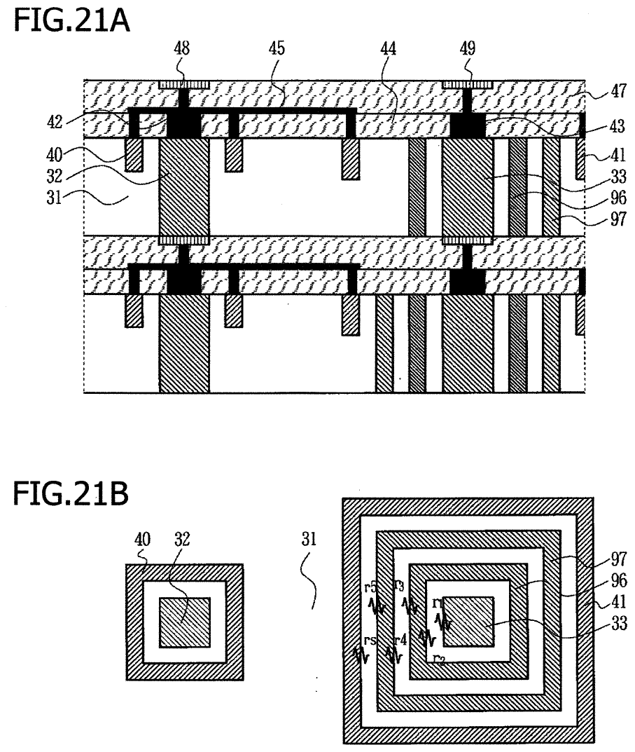

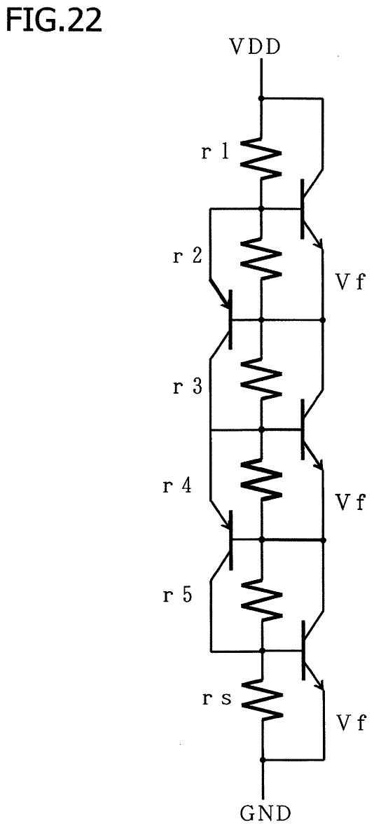

Next, the multilayer semiconductor integrated circuit device according to Example 9 of the present invention is described in reference to FIGS. 21 and 22. Example 9 is the same as Example 1, except that the resistance between the collector and the base is increased by providing a double n⁺⁺ type guard ring around the periphery of the n⁺⁺ type well region for V_{DD}. In order to make the description simpler, the p type well region and the n type well region are omitted, and at the same time, the illustrated multilayer structure has two layers.

FIG. 21 shows diagrams illustrating the configuration between substrate contact electrodes in the multilayer semiconductor integrated circuit device according to Example 9 of the present invention. FIG. 21(a) is a cross-sectional diagram, and FIG. 21(b) is a plan diagram. As illustrated in FIG. 21(a), a double n⁺⁺ type guard ring 96, 97 is provided between the n⁺⁺ type well region 33 and the p⁺ type substrate contact region 41.

In this case, as illustrated in FIG. 21(b), a resistance r1 is generated due to a depletion layer between the n⁺⁺ type well region 33 and the p⁻ type Si substrate 31, and resistances r2 and r3 are generated due to a depletion layer between the p⁻ type Si substrate 31 and the n⁺⁺ type guard ring 96. In addition, resistances r4 and r5 are generated due to a depletion layer between the p⁻ type Si substrate 31 and the n⁺⁺ type guard ring 97. In this case as well, the parasitic resistance rs between the emitter and the base becomes the resistance between the n⁺⁺ type well region 32 and the p⁻ type Si substrate 31.

FIG. 22 illustrates an equivalent circuit between substrate contact electrodes in the multilayer semiconductor integrated circuit device according to Example 9 of the present invention. The voltage that is applied between the emitter and the base of the parasitic npn bipolar transistor on the n⁺⁺ type well region 32 side becomes V_{DD} multiplied by rs/(rs+r5+r4+r3+r2+r1), which is much smaller than V_{f}, and therefore, the parasitic npn bipolar transistor can be further effectively prevented from turning on. Here, this structure where the double n⁺⁺ type guard ring is provided can be applied to Examples 2 through 7. Furthermore, a higher than triple n⁺⁺ type guard ring may be provided instead of the double n⁺⁺ guard ring.

### Example 10

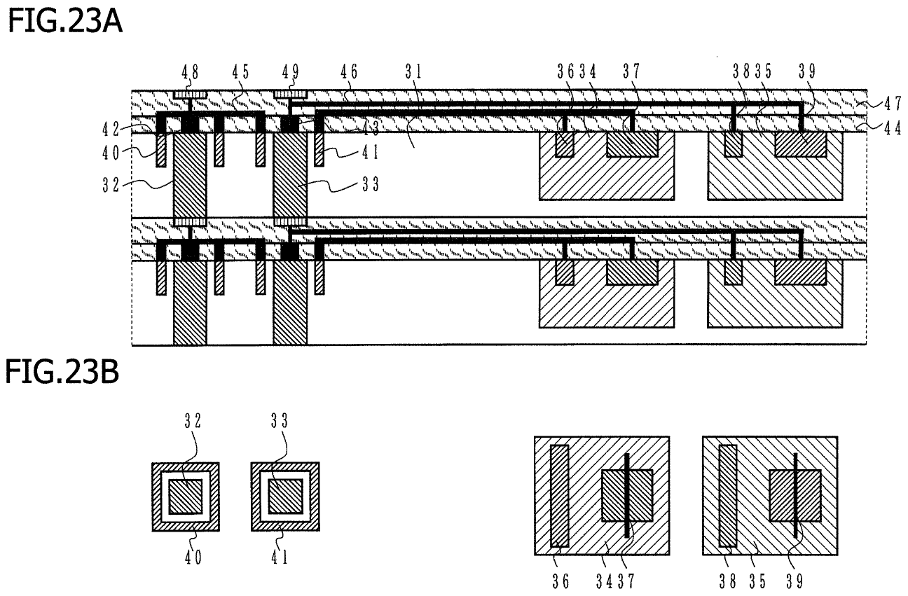

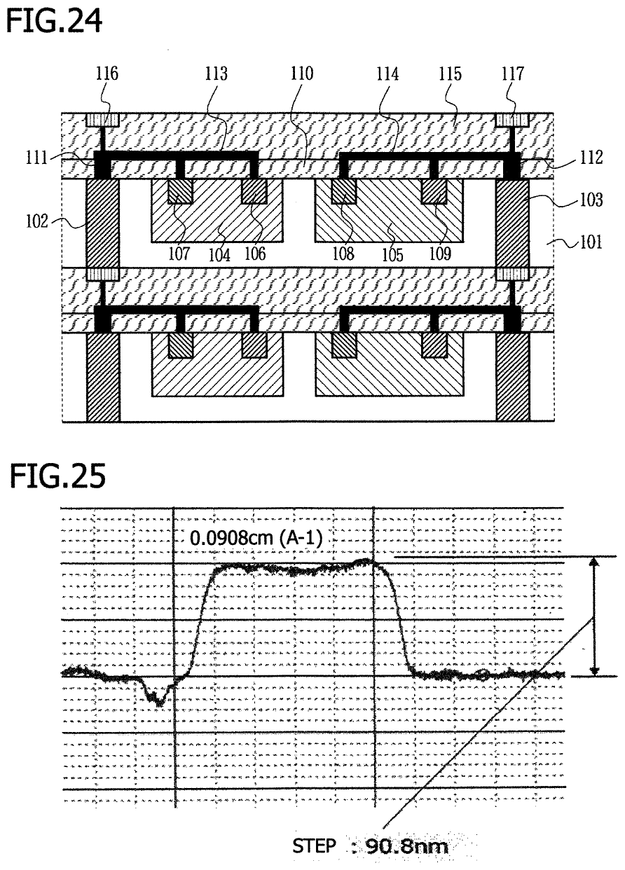

Next, the multilayer semiconductor integrated circuit device according to Example 10 of the present invention is described in reference to FIG. 23. In Example 10, the n⁺⁺ type well region 33 is arranged in proximity to the n⁺⁺ type well region 32, and at the same time, the p type well region 34 and the n type well region 33 are arranged outside the n⁺⁺ type well region 33. FIG. 23 shows diagrams illustrating the multilayer semiconductor integrated circuit device according to Example 10 of the present invention. FIG. 23(a) is a cross-sectional diagram, and FIG. 23(b) is a plan diagram, where the configuration is the same as that in Example 1, except the arrangement of the regions. In order to make the description simpler, the illustrated multilayer structure has two layers. In addition, in order to clarify the state of connection of wire layers, the wire layer 45 and the wire layer 46 are illustrated in different levels; however, the actual wire layers are formed in the same process.

As illustrated in FIG. 23, the n⁺⁺ type well region 33 is arranged between the n⁺⁺ type well region 32 and the n type well region 35, and therefore, the n⁺⁺ type well region 32 that is connected to the potential of a grounded power supply absorbs the collector current of the parasitic bipolar transistor with the n type well region 35 being the collector, and thus, the parasitic bipolar transistor can be effectively prevented from turning on.

In addition, the p type well region 34 is arranged between the n⁺⁺ type well region 32 and the n type well region 35, and therefore, the base of the parasitic bipolar transistor with the n type well region 35 being the collector becomes long, which can make the current amplification effect of the parasitic bipolar transistor smaller. Here, this effect can be gained in the case where the distance between the n⁺⁺ type well region 32 and the n type well region 35 is large; however, the p type well region 34 is arranged between the n⁺⁺ type well region 32 and the n type well region 35 in order to use the space efficiently. This configuration can be applied to Examples 2 through 9.

### REFERENCE SIGNS LIST

1₁ first semiconductor integrated circuit device
1₂ second semiconductor integrated circuit device
2₁ first p type semiconductor body
2₂ second p type semiconductor body
3₁ first n type semiconductor region
3₂ second n type semiconductor region
4₁ first p type semiconductor region
4₂ second p type semiconductor region
5₁ first n type through semiconductor region
5₂ third n type through semiconductor region
6₁ second n type through semiconductor region
6₂ fourth n type through semiconductor region
7₁ first p type contact region
7₂ third p type contact region
8₁ second p type contact region
8₂ fourth p type contact region
9₁ third electrode
9₂ first electrode
10₁ fourth electrode
10₂ second electrode
11₁˜12₂ wire
13, 57 depletion layer
31, 71, 101 p⁻ type Si substrate
32, 33, 72, 73 n⁺⁺ type well region
34, 74, 104 p type well region
35, 75, 105 n type well region
36, 76, 106 p⁺ type contact region
37, 77, 78, 107 n type region
38, 79, 108 n⁺ type contact region
39, 80, 109 p type region
40, 41, 81, 82 p⁺ type substrate contact region
42, 43, 83, 84, 111, 112 contact electrode
44, 47, 62, 85, 88, 110, 115 interlayer insulating film
45, 46, 86, 87, 113, 114 wire layer
48, 49, 89, 90, 116, 117 surface electrode
50 support substrate
51, 91 package substrate
52 adhesive
53, 54 power supply pad
55, 56 bonding wire
59 SiO₂ protective film
60, 61 rear surface electrode
63, 64 surface plug electrode
65 n type deep well region
66, 94 communication coil
92 bump
93 GND pad
94 V_{DD} pad
95 signal pad
96, 97 n⁺⁺ type guard ring
102 p⁺⁺ type well region
103 n⁺⁺ type well region

1. A multilayer semiconductor integrated circuit device, comprising at least a first semiconductor integrated device and a second semiconductor integrated device, wherein
the first semiconductor integrated circuit device includes:
a first p type semiconductor body;
a first n type semiconductor region that is provided in the first p type semiconductor body, and where an element including a transistor is provided;
a first p type semiconductor region that is provided in the first p type semiconductor body, and where an element including a transistor is provided;
a first n type through semiconductor region that penetrates through the first p type semiconductor body in the direction of the thickness, and at the same time is connected to the potential of a grounded power supply; and
a second n type through semiconductor region that penetrates through the first p type semiconductor body in the direction of the thickness, and at the same time is connected to the potential of a positive power supply; and wherein
the second semiconductor integrated circuit device forms a multilayer structure together with the first semiconductor integrated circuit device, and has a first electrode that is electrically connected to the first n type through semiconductor region and a second electrode that is connected to the second n type through semiconductor region; and wherein
a first p type contact region that is connected to the potential of the grounded power supply is provided in proximity to the first n type through semiconductor region, and
a second p type contact region that is connected to the potential of the grounded power supply is provided in proximity to the second n type through semiconductor region; and wherein
a parasite bipolar transistor of which the emitter is the first n type through semiconductor region, of which the base is the first p type semiconductor body, and of which the collector is the second n type through semiconductor region, is prevented from being in the turned on state by setting the resistance between the base and the emitter smaller than the resistance between the collector and the base.

2. The multilayer semiconductor integrated circuit device according to claim 1, wherein the first p type semiconductor body has a thickness of 4 μm or less.

3. (canceled)

4. (canceled)

5. The multilayer semiconductor integrated circuit device according to claim 1, wherein
the first p type contact region surrounds the periphery of the first n type through semiconductor region, and
the second p type contact region surrounds the periphery of the second n type through semiconductor region.

6. The multilayer semiconductor integrated circuit device according to claim 1, wherein
the side of the first p type contact region that faces the first n type through semiconductor region is longer than the side of the first n type through semiconductor region that faces the first p type contact region, and
the side of the second p type contact region that faces the second n type through semiconductor region is longer than the side of the second n type through semiconductor region that faces the second p type contact region.

7. The multilayer semiconductor integrated circuit device according to claim 1, wherein the first p type contact region and the second p type contact region are an integrated p type semiconductor region having a continuous pattern.

8. The multilayer semiconductor integrated circuit device according to claim 1, wherein the first p type contact region and the second p type contact region form a single p type semiconductor region in a frame form, and the first n type through semiconductor region and the second n type semiconductor region are arranged inside the single p type semiconductor region in a frame form.

9. The multilayer semiconductor integrated circuit device according to claim 1, further comprising an n type semiconductor region in a frame form that is provided via a portion of the first p type semiconductor body around the periphery of the second n type through semiconductor region that is connected to the potential of the positive power supply.

10. The multilayer semiconductor integrated circuit device according to claim 9, wherein in the same manner as the n type semiconductor region in a frame form, multiple n type semiconductor regions in a frame form are provided.

11. The multilayer semiconductor integrated circuit device according to claim 1, wherein
the second semiconductor integrated circuit device includes:
a second p type semiconductor body;
a second n type semiconductor region that is provided in the second p type semiconductor body, and where an element including a transistor is provided;
a second p type semiconductor region that is provided in the second p type semiconductor body, and where an element including a transistor is provided;
a third n type through semiconductor region that penetrates through the second p type semiconductor body in the direction of the thickness, and at the same time is connected to the potential of the grounded power supply; and
a fourth n type through semiconductor region that penetrates through the second p type semiconductor body in the direction of the thickness, and at the same time is connected to the potential of the positive power supply, and
the multilayer semiconductor integrated circuit device is provided with the first electrode that is electrically connected to the third n type through semiconductor region, and the second electrode that is electrically connected to the fourth n type through semiconductor region.

12. The multilayer semiconductor integrated circuit device according to claim 1, wherein no electrode is provided on an exposed surface of the first n type through semiconductor region or the second n type through semiconductor region on the surface of the first semiconductor integrated circuit device that faces the second semiconductor integrated circuit device.

13. The multilayer semiconductor integrated circuit device according to claim 12, wherein
a plurality of first plug electrodes are provided on a surface of the first electrode that is provided on the second semiconductor integrated circuit device,
a plurality of second plug electrodes are provided on a surface of the second electrode that is provided on the second semiconductor integrated circuit device,
the first plug electrodes make direct contact on an exposed surface of the first n type through semiconductor region, and
the second plug electrodes make direct contact on an exposed surface of the second n type through semiconductor region.

14. The multilayer semiconductor integrated circuit device according to claim 11, wherein the arrangement of the elements in the first semiconductor integrated circuit device and the arrangement of the elements in the second semiconductor integrated circuit device are the same.

15. The multilayer semiconductor integrated circuit device according to claim 11, wherein the arrangement of the elements in the first semiconductor integrated circuit device and the arrangement of the elements in the second semiconductor integrated circuit device are different.

16. The multilayer semiconductor integrated circuit device according to claim 1, a plurality of semiconductor integrated circuit devices that are the same as the first semiconductor integrated circuit device are layered on top of each other.

17. The multilayer semiconductor integrated circuit device according to claim 1, wherein the sum of the resistance value of the first n type through semiconductor region and the contact resistance between the first n type through semiconductor region and the electrode as well as the sum of the resistance value of the second n type through semiconductor region and the contact resistance between the second n type through semiconductor region and the electrode are 3 mΩ, or less.

18. The multilayer semiconductor integrated circuit device according to claim 1, wherein the first p type semiconductor region is electrically separated from the first p type semiconductor body by means of an n type separation layer, and the n type separation layer is exposed from the rear surface of the first p type semiconductor body.

19. The multilayer semiconductor integrated circuit device according to claim 1, wherein the second n type through semiconductor region is arranged between the first n type through semiconductor region and the first n type semiconductor region.

20. The multilayer semiconductor integrated circuit device according to claim 1, wherein the first p type semiconductor region is arranged between the first n type through semiconductor region and the first n type semiconductor region.

21. The multilayer semiconductor integrated circuit device according to claim 1, wherein the first semiconductor integrated circuit device and the second semiconductor integrated circuit device have a coil for the transmission and reception of a signal.
